(19) United States
(12) Patent Application Publication
(10) Pub. No.: US 2022/0064785 A1
(43) Pub. Date: Mar. 3, 2022

(54) APPARATUS AND METHODS FOR GAS PHASE PARTICLE REDUCTION

(71) Applicant: Applied Materials, Inc., Santa Clara, CA (US)

(72) Inventors: Muhannad MUSTAFA, Milpitas, CA (US); Haoyan SHA, San Jose, CA (US); Muhammad M. RASHEED, San Jose, CA (US); Chi-Chou LIN, San Jose, CA (US); Mario D. SILVETTI, Fountain Hills, AZ (US); Bin CAO, Fremont, CA (US); Shihchung CHEN, Cupertino, CA (US); Yongjing LIN, San Jose, CA (US)

(21) Appl. No.: 17/010,518

(22) Filed: Sep. 2, 2020

(51) Int. Cl. C23C 16/44

(52) U.S. Cl. CPC C23C 16/4401

(57) ABSTRACT

Embodiments of the present disclosure generally relate chamber lids and methods of using such for gas-phase particle reduction. In an embodiment is provided a chamber lid that includes a top wall, a bottom wall, a plurality of vertical sidewalls, and an interior volume within the chamber lid defined by the top wall, the bottom wall, and the plurality of vertical sidewalls. The chamber lid further includes a plurality of air flow apertures, wherein the plurality of air flow apertures is configured to fluidly communicate air into the interior volume and out of the interior volume, and a mesh disposed on a face of at least one of the air flow apertures of the plurality of air flow apertures. In another embodiment is provided a method of processing a substrate in a substrate processing chamber, the substrate processing chamber comprising a chamber lid as described herein.

### BACKGROUND

### Field

Embodiments of the present disclosure generally relate to substrate processing equipment and methods for gas-phase particle reduction. More specifically, embodiments of the present disclosure generally relate to chamber lids and methods of using such for gas-phase particle reduction.

### Description of the Related Art

Substrate processing apparatus are used to perform fabrication processes, e.g., deposition operations and etching operations, on substrates and semiconductor wafers. Substrate processing apparatus typically include a processing chamber where such fabrication operations can be performed. The processing chamber generally includes a chamber body, an inlet, a chamber lid assembly, and a substrate support. During deposition processes, a precursor gas is typically directed through a showerhead or other inlet situated near the top of the chamber. The precursor gas reacts to form a layer of material on the surface of a substrate that is positioned on a heated substrate support.

During substrate processing, a temperature gradient exists in the process volume above the substrate surface due to, at least, the chamber lid. Typically, the areas of the processing volume above the center of the substrate are warmer than the areas above the substrate edges (e.g., about 5° C. or more). The higher temperatures result in the production of particles from gas-phase reactions of the precursor gas(es). Such particles undesirably stick to surfaces inside the substrate processing chamber, leaving behind residues that require costly maintenance interruptions for cleaning. The particles can also adhere to the substrate being processed, negatively affecting the uniformity of material deposited on the substrate and increasing production costs. For example, in an etching process, the particles adhered to the substrate surface can problematically function as a mask, thereby generating etching residues. Further, in a film-forming process, the particles adhered to the substrate surface can function as nuclei for growth, leading to degradation in film quality.

Conventional techniques to reduce the gas phase reaction, thereby reducing the amount of particles, include decreasing the substrate support temperature and decreasing the pressure of the processing chamber. However, both methods negatively affect substrate throughput.

There is a need for new and improved chamber lids and methods for gas-phase particle reduction.

### SUMMARY

Embodiments of the present disclosure generally relate to substrate processing equipment and methods for gas-phase particle reduction. More specifically, embodiments of the present disclosure generally relate to chamber lids and methods of using such for gas-phase particle reduction.

In an embodiment is provided a chamber lid that includes a top wall, a bottom wall, a plurality of vertical sidewalls, and an interior volume within the chamber lid defined by the top wall, the bottom wall, and the plurality of vertical sidewalls. The chamber lid further includes a plurality of air flow apertures, wherein the plurality of air flow apertures is configured to fluidly communicate air into the interior volume and out of the interior volume, and a mesh disposed on a face of at least one of the air flow apertures of the plurality of air flow apertures.

In another embodiment is provided a chamber lid that includes a top wall, a bottom wall, a plurality of vertical sidewalls, and an interior volume within the chamber lid defined by the top wall, the bottom wall, and the plurality of vertical sidewalls. The chamber lid further includes a plurality of air flow apertures, wherein: one or more air flow apertures of the plurality of air flow apertures is on a first vertical sidewall of the chamber lid, one or more air flow apertures of the plurality of air flow apertures is on a second vertical sidewall of the chamber lid, one or more air flow apertures on the top wall of the chamber lid, and the plurality of air flow apertures are configured to fluidly communicate air moving inwardly from an exterior surface of the plurality of vertical sidewalls to the interior volume, and moving outwardly from the interior volume through the one or more air flow apertures on the top wall of the chamber lid. The chamber lid further includes a mesh disposed on a face of at least one of the air flow apertures of the plurality of air flow apertures.

In another embodiment is provided a method of processing a substrate that includes introducing the substrate into a processing volume of a substrate processing chamber, the substrate processing chamber comprising a chamber lid as described herein, and performing one or more operations on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and the disclosure may admit to other equally effective embodiments.

FIG. 1 is a schematic view of an example substrate processing chamber in accordance with at least one embodiment of the present disclosure.

FIG. 2 is a schematic of an example chamber lid according to at least one embodiment of the present disclosure.

FIG. 3 illustrates air flow movement into and out of an example chamber lid according to at least one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to substrate processing equipment and methods for gas-phase particle reduction. More specifically, embodiments of the present disclosure generally relate to chamber lids and methods of using such for gas-phase particle reduction. The inventors have discovered a new and improved chamber lid for substrate processing apparatus that exhibits improved temperature uniformity across the chamber lid. The improved temperature uniformity of the chamber lid improves the temperature uniformity in the space above the substrate from the center to the edge. The apparatus (e.g., chamber lid) and methods described herein enables efficient power control with a low-temperature set point and uniform (or nearly uniform) lid temperature. Efficient power control can be enabled by embodiments described herein for at least the reason that the heat transfer from the chamber body to the lid lowers the proportional-integral-derivative (PID) controller power for the chamber lid temperature. The apparatus and methods described herein also ensures that the current process baseline uniformity and thickness of substrates is maintained.

In some embodiments, the chamber lid described herein includes a top wall, a bottom wall, a plurality of vertical sidewalls, and an interior volume defined by the top wall, the bottom wall, and the plurality of sidewalls. The chamber lid has one or more apertures (e.g., openings) and mesh disposed over, under, and/or within the one or more apertures. The one or more apertures, e.g., air flow apertures, are configured to channel air flow into and out of an interior volume of the chamber lid. The one or more apertures can allow air flow to move inwardly from an exterior of the chamber lid to an interior volume of the chamber lid, and move outwardly from the interior volume of the chamber lid to the exterior of the chamber lid using, e.g., natural convection processes. The one or more apertures located on the vertical sidewalls of the chamber lid can serve as air flow inlets and the one or more apertures on the top wall of the chamber lid can serve as air flow outlets.

During substrate processing, a temperature gradient exists above the substrate surface due to, at least, the chamber lid. Typically, the areas above the center of the substrate are warmer than the areas above the substrate edges (e.g., about 5° C. to about 10° C. or more). The higher temperatures result in the production of particles from gas-phase reactions of the precursor gas(es). Such particles undesirably stick to surfaces inside the process chamber, leaving behind residues that require costly maintenance interruptions for cleaning. The particles can also adhere to the substrate being processed, negatively affecting the uniformity of material deposited on the substrate and increasing production costs. Periodic cleaning and maintenance of the exposed surfaces of the processing chamber also increases the downtime of the processing apparatus. For example, the surfaces of the chamber lid assembly as well as other tools that are exposed to process gas(es) are typically cleaned periodically to remove deposition reactant from these exposed surfaces. To accomplish this, the chamber lid assembly usually is completely taken apart to separate the gas distribution plates from each other and to thereby access the exposed surfaces of these plates. Disassembling the chamber lid assembly for cleaning takes a relatively long time. Moreover, reassembling the chamber lid assembly after cleaning requires the gas seals and the gas distribution plates to be realigned, which can be a difficult, time-consuming process.

Conventional techniques for gas-phase particle reduction include decreasing the substrate support temperature and decreasing the pressure of the process volume within the substrate processing chamber. Such strategies, however, can negatively affect the deposition thickness and/or the substrate throughput, thereby increasing production costs. In contrast, the apparatus and methods described herein can maintain deposition thickness and/or substrate throughput while at the same time significantly reduce the amount of particles produced. For example, the apparatus and methods described herein can reduce the amount of particles by about 4-5 times or more relative to conventional techniques. Accordingly, the apparatus and methods described herein show an improved mean wafer between clean (MWBC) value, such as from about 2,000 to about 10,000. Further, the apparatus and methods described herein are compatible with established practices in the semiconductor fabricating industry. For example, the apparatus and processes described herein are compatible with n-type and p-type metal semiconductor processes. Since, n-type and p-type metal semiconductor processes do not have an in-situ cleaning process, the apparatus and processes described herein significantly improve throughput and lower production costs for both n-type and p-type metal semiconductor processes.

As described herein, the air that flows through the new and improved chamber lid can allow for increased heat removal from the chamber lid relative to conventional chamber lids, thereby allowing for a reduced chamber lid temperature compared to conventional chamber lids. Moreover, the chamber lid described herein can be free of a heat source that heats the chamber lid. That is, the chamber lid described herein provides power savings and cost savings. The chamber lid described herein can have a temperature that is at or near to a temperature of the chamber body. The one or more apertures allow movement of air through the chamber lid, and can ensure a uniform (or nearly uniform) air flow stream through the center of the chamber lid and minimize the center-to-edge temperature non-uniformity of the chamber lid. By improving the center-to-edge temperature non-uniformity of the chamber lid, the temperature difference between an edge region of the substrate and a center region of the substrate can also be minimized. Moreover, by improving the enter-to-edge temperature non-uniformity of the chamber lid, the temperature non-uniformity of the processing volume above the substrate can also be minimized.

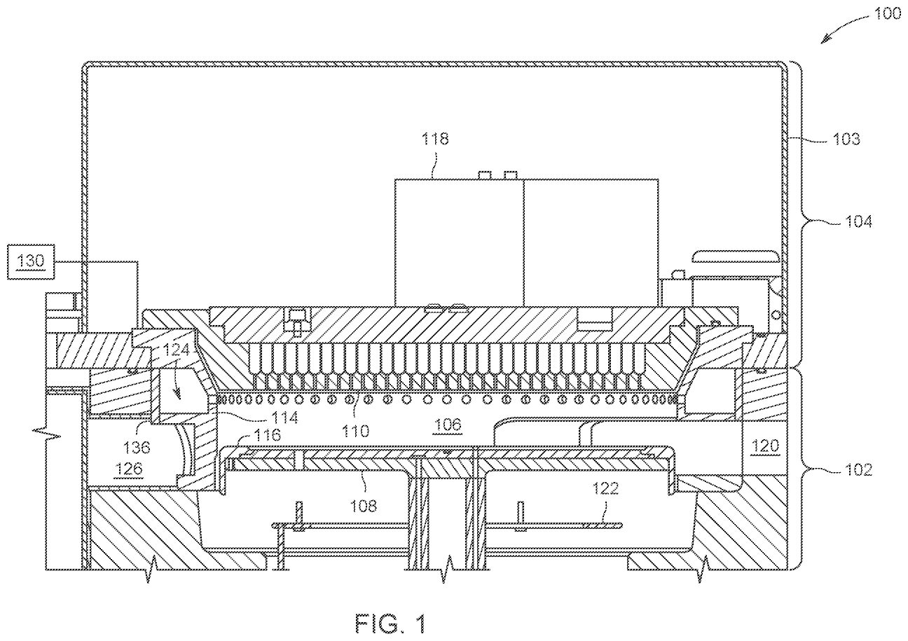

FIG. 1 is a schematic view of a substrate processing chamber 100 in accordance with some embodiments of the present disclosure. Substrate processing chamber 100 includes a chamber body 102 and a chamber lid assembly 104 having a processing volume 106 defined within the chamber body 102 and beneath the chamber lid assembly 104. The chamber lid assembly 104 includes a chamber lid 103. A slit valve 120 in the chamber body 102 provides access for a robot (not shown) to deliver and retrieve a substrate, such as a 200 mm, 300 mm, or 450 mm semiconductor wafer, a glass substrate, etc., to and from the substrate processing chamber 100. A substrate support 108 supports a substrate on a substrate receiving surface in the substrate processing chamber 100. The substrate support 108 is mounted to a lift motor for raising and lowering the substrate support 108 and the substrate when disposed on the substrate support 108. A lift plate 122, connected to a lift motor, is mounted in the substrate processing chamber 100 to raise and lower lift pins movably disposed through the substrate support 108. The lift pins raise and lower the substrate over the surface of the substrate support 108. The substrate support 108 can include a vacuum chuck, an electrostatic chuck, and/or a clamp ring for securing the substrate to the substrate support 108 during processing.

The temperature of the substrate support 108 can be adjusted to control the temperature of the substrate. For example, substrate support 108 can be heated using an embedded heating element, such as a resistive heater, or can be heated using radiant heat, such as heating lamps configured to provide heat energy to the substrate support 108. In some embodiments, an edge ring 116 is disposed atop a peripheral edge of the substrate support 108. The edge ring 116 includes a central opening sized to expose the support surface of the substrate support 108. The edge ring 116 can further include a skirt, or downwardly extending annular lip to protect the sides of the substrate support 108.

In some embodiments, a liner 114 is disposed along the interior walls (e.g., one or more sidewalls) of the chamber body 102 to protect the chamber body 102 from corrosive gases or deposition of materials during operation. The liner 114 can include one or more heating elements coupled to a heater power source 130. The heater power source 130 can be a single power source or a plurality of power sources coupled to respective ones of the one or more heating elements. In some embodiments, a shield 136 is disposed about the liner 114 to protect the chamber body 102 from corrosive gases or deposition of materials. In some embodiments, the liner 114 and the shield 136 define a pumping volume 124. The liner 114 includes a plurality of openings to fluidly couple the pumping volume 124 to the processing volume 106. In such embodiments, the pumping volume 124 is further fluidly coupled to a pump port 126 to facilitate evacuation of gases from the substrate processing chamber 100 and maintaining a predetermined pressure or pressure range inside the substrate processing chamber 100 via a vacuum pump coupled to the pump port 126. A gas delivery system 118 is coupled to the chamber lid assembly 104 to provide a gas, such as a process gas and/or a purge gas, to the processing volume 106 through a showerhead 110. The showerhead 110 is disposed in the chamber lid assembly 104 generally opposite the substrate support 108 and includes a plurality of gas distribution holes to provide process gases to the processing volume 106.

In an example processing operation, a substrate is delivered to the substrate processing chamber 100 through the slit valve 120 by a robot (not shown). The substrate is positioned on the substrate support 108 through cooperation of the lift pins and the robot. The substrate support 108 raises the substrate into close opposition to a lower surface of the showerhead 110. A first gas flow can be injected into the processing volume 106 by the gas delivery system 118 together or sequentially (e.g., in pulses) with a second gas flow. The first gas flow can contain a continuous flow of a purge gas from a purge gas source and pulses of a reactant gas from a reactant gas source or can contain pulses of a reactant gas from the reactant gas source and pulses of a purge gas from the purge gas source. The second gas flow can contain a continuous flow of a purge gas from a purge gas source and pulses of a reactant gas from a reactant gas source or can contain pulses of a reactant gas from a reactant gas source and pulses of a purge gas from a purge gas source. The gas is then deposited on the surface of substrate. Excess gas, by-products, and the like flow through the pumping volume 124 to the pump port 126 and are then exhausted from substrate processing chamber 100.

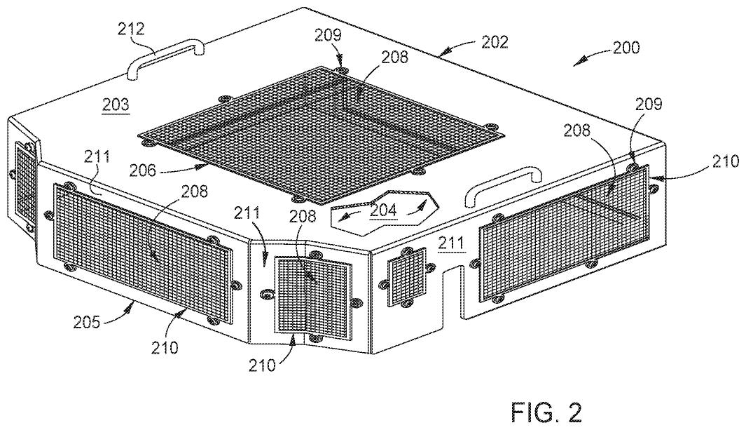

FIG. 2 is a schematic of an example chamber lid 200 according to at least one embodiment of the present disclosure. Chamber lid 200 can be the chamber lid of any suitable chamber lid assembly such as chamber lid assembly 104.

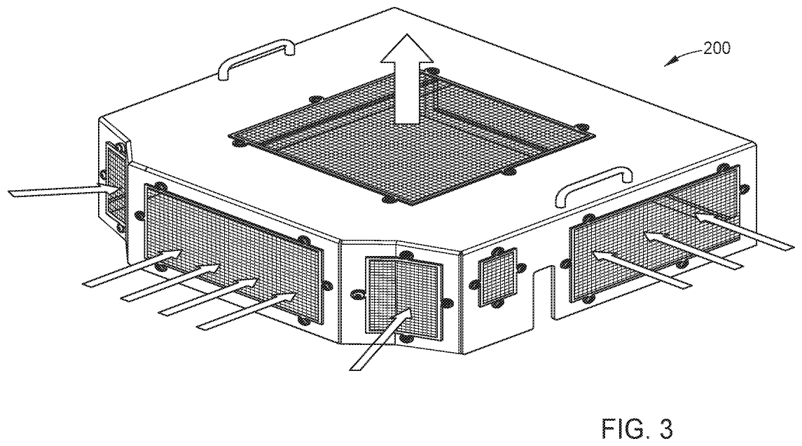

Chamber lid 200 includes a top wall 203 having an upper (exposed) surface and a lower (interior) surface, a bottom wall 205 having an upper (interior) surface, and a plurality of vertical sidewalls 211. An interior volume 204 within the chamber lid 200 is defined by the lower interior surface of the top wall 203, the upper (interior) surface of the bottom wall 205, and the plurality of vertical sidewalls 211. The chamber lid includes an aperture 206 (e.g., an opening) on the top wall 203 of the chamber lid 200. As shown, one aperture 206 on the top wall is provided. In some embodiments, a greater number of apertures is contemplated. The aperture 206 on the top wall 203 of the chamber lid 200 serves as, at least, an air flow outlet. The chamber lid includes aperture(s) 210 located on one or more of the vertical sidewalls 211 of the chamber lid 200. As shown, five apertures 210 on the vertical sidewalls 211 is provided. In some embodiments, a greater number or lesser number of apertures 210 is contemplated. The aperture(s) 210 serve as, at least, an air flow inlet. The apertures 206 and 210 are configured to fluidly communicate air inwardly from an exterior 202 of the chamber lid 200 to the interior volume 204 and outwardly from the interior volume 204 to the exterior 202 of the chamber lid 200. For example, the air flow moves inwardly through the aperture(s) 210 of vertical sidewalls 211 from the exterior 202 to the interior volume 204 of the chamber lid 200, and air flow moves outwardly through the aperture 206 of the top wall 203 of the chamber lid 200 towards the exterior 202 as indicated by the flow arrows in FIG. 3. A processing volume, e.g., processing volume 106, can be located at a position beneath the bottom wall 205 of the chamber lid 200 of the chamber lid assembly 104.

Within the aperture 206 can be disposed a mesh 208 (e.g., a wire screen) such as a metal meshing. Additionally, or alternatively, the mesh 208 can be disposed on a top face and/or a bottom face of the aperture 206. For example, the mesh 208 can be disposed on the top face of the aperture 206 and coupled to the top wall 203 of the chamber lid 200. As another example, the mesh 208 can be disposed on the bottom face of the aperture 206 and coupled to the interior surface of the chamber lid 200. In each of these configurations, the interior volume 204 and the exterior 202 of the chamber lid 200 are isolated by a mesh 208 on a face of the aperture 206 and/or within the aperture 206. The mesh 208 can be secured to the chamber lid by one or more fasteners 209, such as bolts, to facilitate removal and/or replacement.

Within the aperture(s) 210 of the vertical sidewalls 211 can be disposed mesh 208 (e.g., a wire screen) such as a metal meshing. Additionally, or alternatively, the mesh 208 can be disposed on an exterior side face and/or an interior side face of the aperture(s) 210. For example, the mesh can be disposed on the exterior face of the aperture(s) 210 and coupled to the outer surface of vertical sidewall 211. As another example, the mesh 208 can be disposed on the inner face of the aperture(s) 210 and coupled to the interior surface of vertical sidewall 211. In each of these configurations, the interior volume 204 and the exterior 202 of the chamber lid 200 are isolated by a mesh 208 on a face of the aperture(s) 210 and/or within the aperture(s) 210. The mesh 208 can be secured to the chamber lid by one or more fasteners 209. The chamber lid 200 can optionally include one or more handles 212 to move the chamber lid 200, e.g., upward or downward.

Although only certain vertical sidewalls 211 of the chamber lid 200 are shown to include one or more apertures and mesh in FIG. 2, it is contemplated that other vertical sidewalls of the chamber lid can include one or more apertures and mesh in the same or similar arrangements. In some embodiments, a greater number or lesser number of aperture 206, aperture(s) 210, and mesh 208 is contemplated. In addition, although the aperture 206 is located at a position that is substantially central to the top wall 203, the aperture 206 can be in different location(s) on the top wall 203. Similarly, although the aperture(s) 210 are, independently, located at a position that is substantially central to each of the one or more vertical sidewalls 211, the aperture(s) 210 can be at different location(s) on the one or more vertical sidewalls 211. In some embodiments, the angled mesh sections at or near the corners of the chamber lid can be designed based on the shape of the chamber lid plate to be covered.

The chamber lid 200 can increase heat removal from the chamber lid 200 by, e.g., convection. For example, and as indicated by the flow arrows in FIG. 3, the air flow naturally transfers inwardly from the exterior 203 of the chamber lid 200 through aperture(s) 210 of the one or more vertical sidewalls 211 and toward the interior volume 204, and the air flow naturally transfers outwardly from the interior volume 204 through aperture 206 and toward the exterior 203 of the chamber lid 200. As shown in FIG. 3, the apertures direct air flow from the sidewall(s) of the chamber lid to the interior volume of the chamber lid. The air flow is then channeled out of the interior volume through the top wall of the chamber lid. As such, the heat of the chamber lid can be regulated.

Dimensions of aperture 206 and aperture(s) 210 are chosen based on, at least, the amount of air flow desired. In some embodiments, the area of the aperture(s) is from about 15 mm² to about 50 mm² to about, such as from about 20 mm² to about 45 mm², such as from about 25 mm² to about 40 mm², such as from about 30 mm² to about 35 mm². In at least one embodiment, the area of the mesh is about 20 mm² to about 30 mm², such as about 25 mm².

In some embodiments, the aperture 206 and aperture(s) 211 can be variably opened and/or the amount of each aperture can be variable (e.g., a variable mechanism or setting). For example, plates and/or flaps can be moveably disposed on a face of the apertures to block or partially block one or more apertures. As shown, and as non-limiting examples, the shapes of the apertures are square and/or rectangular. It is contemplated that other shapes of the apertures can be used, e.g., circular, elliptical, oval, or shapes with three or more sides, e.g., triangular, pentagonal, hexagonal, octagonal, or a combination thereof.

The mesh 208 can be made of a variety of materials such as plastic and/or metal. The plastic mesh can be, e.g., extruded, oriented, expanded, woven, and/or tubular. The plastic mesh can be made from, e.g., polypropylene, polyethylene, polyvinylchloride, polytetrafluoroethylene, or a combination thereof. Other materials can include aluminum, cast iron, glass, high-temperature silicone, steel, ceramic, or a combination thereof. The metal mesh can be woven, knitted, welded, expanded, photochemically etched, and/or electroformed from a metal-containing material such as steel.

Dimensions of the mesh 208 are chosen based on, at least, the amount of air flow desired and the size of apertures. In some embodiments, the area of the mesh is from about 15 mm² to about 50 mm² to about, such as from about 20 mm² to about 45 mm², such as from about 25 mm² to about 40 mm², such as from about 30 mm² to about 35 mm². In at least one embodiment, the area of the mesh is about 20 mm² to about 30 mm², such as about 25 mm².

Embodiments of the present disclosure also generally relate to methods of using a chamber lid. The chamber lid, e.g., chamber lid 200, provides control of conditions, such as temperature, of the processing volume 106 and of the chamber lid assembly 104. In operation, the substrate is introduced into the processing volume 106 of substrate processing chamber 100, and the substrate is located on the substrate support 108. Process gases flow through the chamber lid assembly 104 in accordance with any desired flow scheme. Temperature set points can be set for the chamber body 102 and the substrate support 108. One or more operations for semiconductor device fabrication can be performed on the substrate. Such operations can include deposition, removal (e.g., etching), patterning, and/or modification of electrical properties, e.g., doping of sources and drains by ion implantation. Deposition includes, but is not limited to, processes that grows or otherwise transfers material onto the substrate, such as atomic layer deposition, chemical vapor deposition, plasma enhanced chemical vapor deposition, physical vapor deposition, and epitaxy. Removal processes include, but are not limited to, etching, which can be dry or wet etching, and chemical mechanical planarization. Patterning, or lithography, operations can also be performed as well as annealing operations.

During processing, the temperature of the substrate support 108 can be, e.g., between about 300° C. and about 450° C. while the chamber body 102 can be about 100° C. to about 150° C. This difference in temperature between the substrate support 108 and the chamber body 102 creates a temperature gradient across the processing volume 106 where the edges of the processing volume are cooler than the center of the processing volume. Conventional chamber lids have a temperature uniformity inside the lid cover of about 2%. The improved chamber lid described herein has a temperature uniformity of about 5%. As a result, less particles are formed by using the chamber lids described herein as compared to conventional chamber lids. Moreover, there is no (or minimal) impact on process transparency. In some examples, the improved chamber lid and methods described herein can reduce the amount of particles by about 4-5 times or more relative to conventional chamber lids and techniques. Accordingly, the apparatus and methods described herein shown an improved MWBC value, such as from about 2,000 to about 10,000, such as from about 3,000 to about 9,000, such as from about 4,000 to about 8,000, such as from about 5,000 to about 7,000.

In addition, the temperature of the chamber lid described herein can be substantially similar to the temperature of the chamber body without the use of a separate power source and heat source for the chamber lid and chamber lid assembly. Typically, the temperature of the chamber body is about 200° C. or less, such as about 175° C. or less, such as about 150° C. or less, such as about 125° C. or less, or from about 100° C. to about 200° C., such as from about 100° C. to about 150° C., such as from about 110° C. to about 140° C., such as from about 120° C. to about 130° C., or from about 100° C. to about 125° C. Due to at least the one or more apertures of the chamber lid described herein, the chamber lid can mimic (or closely mimic) the chamber body temperatures even when the chamber lid is free of a heat source to heat the chamber lid. Accordingly, and in some embodiments, the temperature of the chamber lid is about 200° C. or less, such as about 175° C. or less, such as about 150° C. or less, such as about 125° C. or less, or from about 100° C. to about 200° C., such as from about 100° C. to about 150° C., such as from about 110° C. to about 140° C., such as from about 120° C. to about 130° C., or from about 100° C. to about 125° C.

In some embodiments, the plurality of apertures is configured to control a lid temperature to be about 200° C. or less, such as about 175° C. or less, such as about 150° C. or less, such as about 125° C. or less, or from about 100° C. to about 200° C., such as from about 100° C. to about 150° C., such as from about 110° C. to about 140° C., such as from about 120° C. to about 130° C., or from about 100° C. to about 125° C. In some embodiments, the plurality of air flow apertures is configured to control a lid temperature to be within 100° C. or less of the chamber body temperature, such as about 90° C. or less, such as about 80° C. or less, such as about 70° C. or less, such as about 60° C. or less, such as about 50° C. or less, such as about 40° C. or less, such as about 30° C. or less, such as about 25° C. or less, such as about 20° C. or less, such as about 15° C. or less, such as about 10° C. or less, such as about 5° C. or less. As described above, the placement, dimensions, shapes, etc., of the plurality of apertures on, e.g., the top wall and the vertical sidewalls affect the temperature of the lid. Accordingly, such parameters serve to, at least, maintain certain temperatures that can align with that of the chamber body.

Herein is described improved chamber lids and methods of using such for gas phase particle reduction. The improved chamber lids exhibit superior temperature uniformity and improved power control relative to conventional chamber lids. In addition, the chamber lids described herein significantly reduce the amount of particles produced during processing, thereby permitting less downtime for maintenance and higher substrate throughput.

As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa. The term “coupled” is used herein to refer to elements that are either directly connected or connected through one or more intervening elements.

For the purposes of this disclosure, and unless otherwise specified, all numerical values within the detailed description and the claims herein are modified by “about” or “approximately” the indicated value, and consider experimental error and variations that would be expected by a person having ordinary skill in the art. Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

While the foregoing is directed to examples of the present disclosure, other and further examples of the disclosure may be devised without departing from the basic scope thereof, and the scope thereof is determined by the claims that follow.

1. A chamber lid, comprising:
a top wall;
a bottom wall;
a plurality of vertical sidewalls;
an interior volume within the chamber lid defined by the top wall, the bottom wall, and the plurality of vertical sidewalls;
a plurality of air flow apertures, wherein the plurality of air flow apertures is configured to fluidly communicate air into the interior volume and out of the interior volume; and
a mesh disposed on a face of at least one of the air flow apertures of the plurality of air flow apertures.

2. The chamber lid of claim 1, wherein one or more air flow apertures of the plurality of air flow apertures is on the top wall of the chamber lid.

3. The chamber lid of claim 2, wherein:
one or more air flow apertures of the plurality of air flow apertures is on a first vertical sidewall of the chamber lid;
one or more air flow apertures of the plurality of air flow apertures is on a second vertical sidewall of the chamber lid; or
a combination thereof.

4. The chamber lid of claim 3, wherein the plurality of air flow apertures are configured to fluidly communicate air moving inwardly from an exterior surface of the plurality of vertical sidewalls to the interior volume, and moving outwardly from the interior volume through the one or more air flow apertures of the top wall of the chamber lid.

5. The chamber lid of claim 3, wherein:
the one or more air flow apertures of the plurality of air flow apertures on the first vertical sidewall and the second vertical sidewall are air inlets; and
the one or more air flow apertures of the plurality of air flow apertures on the top wall is an air outlet.

6. The chamber lid of claim 2, wherein:
one or more air flow apertures of the plurality of air flow apertures is on a third vertical sidewall of the chamber lid;
one or more air flow apertures of the plurality of air flow apertures is on a fourth vertical sidewall of the chamber lid; or
a combination thereof.

7. The chamber lid of claim 1, wherein the plurality of air flow apertures is configured to control a chamber lid temperature to be about 150° C. or less.

8. The chamber lid of claim 1, wherein the plurality of air flow apertures is configured to control a chamber lid temperature to be from about 100° C. to about 150° C.

9. The chamber lid of claim 1, wherein the plurality of air flow apertures is configured to control a chamber lid temperature to be within about 50° C. or less of a chamber body located beneath the chamber lid.

10. The chamber lid of claim 1, wherein the plurality of air flow apertures is configured to control a chamber lid temperature to be within about 25° C. or less of a chamber body located beneath the chamber lid.

11. A chamber lid, comprising:
a top wall;
a bottom wall;
a plurality of vertical sidewalls;
an interior volume within the chamber lid defined by the top wall, the bottom wall, and the plurality of vertical sidewalls;
a plurality of air flow apertures, wherein:
one or more air flow apertures of the plurality of air flow apertures is on a first vertical sidewall of the chamber lid,
one or more air flow apertures of the plurality of air flow apertures is on a second vertical sidewall of the chamber lid,
one or more air flow apertures is on the top wall of the chamber lid, and
the plurality of air flow apertures are configured to fluidly communicate air moving inwardly from an exterior surface of the plurality of vertical sidewalls to the interior volume, and moving outwardly from the interior volume through the one or more air flow apertures on the top wall of the chamber lid; and
a mesh disposed on a face of at least one of the air flow apertures of the plurality of air flow apertures.

12. The chamber lid of claim 11, wherein:
the one or more air flow apertures of the plurality of air flow apertures on the first vertical sidewall and the second vertical sidewall are air inlets; and
the one or more air flow apertures of the plurality of air flow apertures on the top wall is an air outlet.

13. The chamber lid of claim 12, wherein:
one or more air flow apertures of the plurality of air flow apertures is on a third vertical sidewall of the chamber lid;
one or more air flow apertures of the plurality of air flow apertures is on a fourth vertical sidewall of the chamber lid; or
a combination thereof.

14. The chamber lid of claim 11, wherein the plurality of air flow apertures is configured to control a chamber lid temperature to be about 150° C. or less.

15. The chamber lid of claim 11, wherein the plurality of air flow apertures is configured to control a chamber lid temperature to be from about 100° C. to about 150° C.

16. The chamber lid of claim 11, wherein the plurality of air flow apertures is configured to control a chamber lid temperature to be within about 50° C. or less of a chamber body located beneath the chamber lid.

17. The chamber lid of claim 11, wherein the plurality of air flow apertures is configured to control a chamber lid temperature to be within about 25° C. or less of a chamber body located beneath the chamber lid.

18. A method of processing a substrate comprising:
introducing the substrate into a processing volume of a substrate processing chamber, the substrate processing chamber comprising a chamber lid, the chamber lid comprising:
a top wall;
a bottom wall;
a plurality of vertical sidewalls;
an interior volume within the chamber lid defined by the top wall, the bottom wall, and the plurality of vertical sidewalls;
a plurality of air flow apertures, wherein the plurality of air flow apertures is configured to fluidly communicate air into the interior volume and out of the interior volume; and
a mesh disposed on a face of at least one of the air flow apertures of the plurality of air flow apertures; and
performing one or more operations on the substrate.

19. The method of claim 18, wherein:
one or more air flow apertures is on the top wall of the chamber lid; and
one or more air flow apertures of the plurality of air flow apertures is on a first vertical sidewall of the chamber lid, one or more air flow apertures of the plurality of air flow apertures is on a second vertical sidewall of the chamber lid, or a combination thereof.

20. The method of claim 19, wherein the plurality of air flow apertures are configured to fluidly communicate air moving inwardly from an exterior surface of the plurality of vertical sidewalls to the interior volume, and moving outwardly from the interior volume through the one or more air flow apertures of the top wall of the chamber lid.
